(19) United States
(12) Patent Application Publication
(10) Pub. No.: US 2026/0025109 A1
(43) Pub. Date: Jan. 22, 2026

(54) ATTENUATOR WITH PVT CORRECTION CIRCUIT

(71) Applicant: MACOM Technology Solutions Holdings, Inc., Lowell, MA (US)

(72) Inventor: Ariel L. Vera Villarroel, Lake Oswego, OR (US)

(21) Appl. No.: 18/779,933

(22) Filed: Jul. 22, 2024

(51) Int. Cl. H03F 1/56; H03F 3/45

(52) U.S. Cl. CPC H03F 1/56; H03F 3/4508

(57) ABSTRACT

Amplifiers incorporating correction or compensation control circuits are described. An example compensated amplifier circuit includes an amplifier circuit and a variable impedance compensation circuit. The variable impedance compensation circuit includes a variable current source, a current divider network, and a variable impedance transistor in one example. The variable impedance transistor includes a field effect transistor in one example, with drain and source terminals coupled between two nodes in the amplifier. The current divider network includes resistors coupled in parallel between an output of the variable current source and terminals of the variable impedance transistor. The compensation circuit can achieve a reduced standard deviation of gain among different amplifiers, even with process-induced, voltage, and temperature variability.

### BACKGROUND

Transistors are commonly used as amplifiers or as parts of amplifier circuits. A transistor, such as a field-effect transistor (FET), can be configured as a certain type or class of amplifier based on which terminal of the transistor is common to both the input and the output of the transistor. For FETs, the amplifier classes include common source, common gate, and common drain. In the case of bipolar junction transistors, the amplifier classes include common emitter, common base, and common collector. Transistors can also be used for a range of other purposes, however, and attenuators as one example can be implemented using FETs when biased in the linear region.

### SUMMARY

Certain aspects of the concepts and embodiments described herein are summarized below. The aspects are representative and not exhaustively listed. In alternate embodiments, certain features and elements can be added, omitted, and interchanged with each other. Additionally, variations, extensions, and modifications to the example embodiments can be achieved by those skilled in the art without departing from the concepts, so as to encompass equivalent and related structures.

An example compensated amplifier circuit includes an amplifier circuit and a variable impedance compensation circuit coupled between two nodes in the amplifier circuit. The variable impedance compensation circuit includes a variable current source, a current divider network, and a variable impedance transistor in one example. In one example, the amplifier circuit includes a differential pair of transistors, the variable impedance transistor includes a field effect transistor, and drain and source terminals of the variable impedance transistor are coupled between two nodes in the amplifier circuit.

In some embodiments, the current divider network includes a plurality of resistors coupled in parallel between an output of the variable current source and terminals of the variable impedance transistor. The current divider network can include a matched pair of resistors coupled in parallel between an output of the variable current source and terminals of the variable impedance transistor. In some examples, a first resistor among the plurality of resistors is coupled between an output of the variable current source and a source terminal of the variable impedance transistor, and a second resistor among the plurality of resistors is coupled between an output of the variable current source and a drain terminal of the variable impedance transistor. The first resistor and the second resistor can be the matched pair of resistors. A third resistor among the plurality of resistors can be coupled between an output of the variable current source and a gate terminal of the variable impedance transistor in some cases.

Another compensated amplifier circuit includes an amplifier circuit and a variable impedance compensation circuit. The variable impedance compensation circuit includes a variable current source, a current divider network, and a variable impedance transistor. The current divider network comprises a plurality of resistors coupled in parallel between an output of the variable current source and terminals of the variable impedance transistor.

Another compensated amplifier circuit includes an amplifier circuit with an input amplifier stage of common collector transistors and a differential pair of transistors, and a variable impedance compensation circuit coupled between two nodes in the amplifier circuit. The variable impedance compensation circuit includes a variable current source, a current divider network, and a variable impedance transistor. The current divider network comprises a plurality of resistors coupled in parallel between an output of the variable current source and terminals of the variable impedance transistor.

### BRIEF DESCRIPTION OF THE DRAWINGS

Aspects of the present disclosure can be better understood with reference to the following drawings. It is noted that the elements in the drawings are not necessarily drawn to scale, with emphasis instead being placed upon illustrating the principles of the examples. In the drawings, like reference numerals designate like or corresponding, but not necessarily the same, elements throughout the several views.

FIG. 1 illustrates an example compensated amplifier circuit according to various examples described herein.

FIG. 2 illustrates another example compensated amplifier circuit according to various examples described herein.

FIG. 3 illustrates another example compensated amplifier circuit according to various examples described herein.

FIG. 4 illustrates another example compensated amplifier circuit according to various examples described herein.

FIG. 5 illustrates another example compensated amplifier circuit according to various examples described herein.

### DETAILED DESCRIPTION

A range of different operating characteristics can be evaluated as part of the design of an amplifier, such as amplifier biasing and bias current density, gain, operating bandwidth, small signal parameters, stability, input and output characteristics, and other operating characteristics. The design of an amplifier can also include an evaluation of operating characteristics over process and operating temperature variations. Amplifier biasing, among other design and operating factors, can be tailored to alter the operating characteristics of amplifiers to some extent.

Two transistors, even when manufactured using the same process techniques, can still exhibit relatively significant variations in operating characteristics. Amplifier biasing circuits, gain control circuits, and related compensation circuits can be relied upon to compensate for variations in gain, bias current, bias current density, and other operating factors among two different transistors manufactured using the same process techniques. Such compensation circuits can generate and adjust bias voltages at amplifier stages, adjust impedances in amplifiers or among amplifier stages, and alter the operation of amplifiers in other ways. The compensation circuits can help to compensate for variations in current density, process or threshold voltages, temperature variations, and other operating characteristics, as referred to as process, voltage, and temperature (PVT) variations, among transistor amplifiers. A gain control circuit, for example, can achieve a reduced standard deviation of gain among different transistor amplifiers manufactured using the same process, even with process-induced variability in the threshold voltages, current densities, and other operating characteristics among the amplifiers.

Broadband attenuators can be implemented using field effect transistors (FETs) when biased in the linear region, in which case a FET appears as a type of variable resistor. Constraints due to bandwidth, linearity, and other factors should be considered when using FETs as attenuators. A FET used as variable resistor has a resistance value controlled via the voltage at the gate terminal of the FET, and the gate terminal voltage is constrained by the safe operating area (SOA) of the FET. Biasing that provides the target control range while keeping the FET within its SOA range with less complexity, power consumption, and chip area is one aspect of the embodiments described herein.

Aspects of amplifiers incorporating attenuation or compensation control circuits with PVT correction features are described herein. An example compensated amplifier circuit includes an amplifier circuit and a variable impedance attenuation or compensation circuit. The variable impedance attenuation or compensation circuit includes a variable current source, a current divider network, and a variable impedance transistor in one example. The variable impedance transistor includes a field effect transistor in one example, with drain and source terminals coupled between two nodes in the amplifier. The current divider network includes resistors coupled in parallel between an output of the variable current source and terminals of the variable impedance transistor. When incorporated into amplifier circuits, the attenuation or compensation circuit can achieve a reduced standard deviation of gain among different amplifiers, even with process-induced, voltage, and temperature variability. The attenuation circuits with PVT correction described herein are applicable for use in a range of different broadband applications. The attenuation circuits are described in connection with amplifiers, but the attenuation circuits can also be incorporated into other circuits, such as equalizers, buffers, drivers, and other circuits.

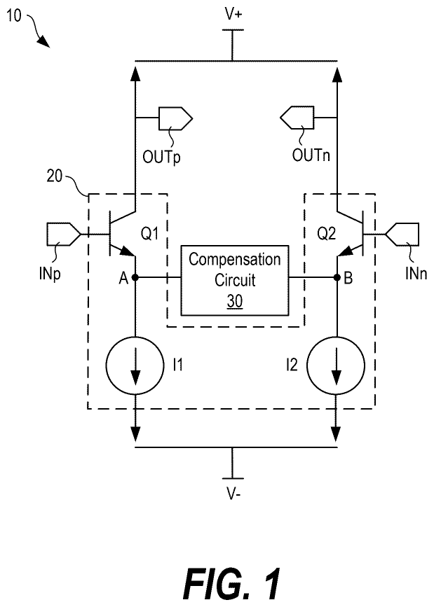

FIG. 1 illustrates an example compensated amplifier circuit 10 (also “amplifier circuit 10”) according to various examples described herein. The amplifier circuit 10 can be embodied in various ways, such as using discrete components, as an integrated circuit device formed on a substrate, or as a combination of discrete components and integrated devices. The amplifier circuit 10 is provided as a representative example of an amplifier stage with a compensation circuit. The amplifier circuit 10 is not exhaustively illustrated in FIG. 1, and the amplifier circuit 10 can include additional components that are not shown.

The amplifier circuit 10 includes an amplifier or amplifier stage 20 (also “amplifier 20”) and a compensation circuit 30 among possibly other components. The amplifier 20 can be used as an amplifier stage for radio frequency (RF) communications, for optical communications, or for other purposes, without limitation. The compensation circuit 30 is coupled between the nodes A and B in the amplifier 20, as described in further detail below, and includes circuitry for gain compensation of the amplifier 20. Other types and configurations of amplifiers and amplifier circuits can also incorporate and rely upon the gain compensation concepts described herein.

The amplifier 20 includes transistors Q1 and Q2, which are electrically coupled together by the compensation circuit 30, and current sources I1 and I2. The transistors Q1 and Q2 are embodied as bipolar junction transistors as depicted in FIG. 1. However, the transistors Q1 and Q2 can be embodied as FETs, and the concepts described herein are not limited to use with amplifiers or transistors of any particular type or technology. The collector of the transistor Q1 is coupled to an upper rail voltage or potential V+, and an output OUTp (e.g., positive or non-inverting output) of the amplifier 20 can be taken from the collector of the transistor Q1. The base of the transistor Q1 operates as an input INp (e.g., positive or non-inverting input) of the amplifier 20. The emitter of the transistor Q1 is coupled to the current source I1 at the node A, and the current source I1 is coupled between the node A and the lower rail voltage or potential V−, which can be ground potential in some cases.

The collector of the transistor Q2 is coupled to V+, and an output OUTn (e.g., negative or inverting output) of the amplifier 20 can be taken from the collector of the transistor Q2. The base of the transistor Q2 operates as another input INn (e.g., negative or inverting input) of the amplifier 20. The emitter of the transistor Q2 is coupled to the current source I2 at the node B, and the current source I2 is coupled between the node B and the lower rail voltage or potential V−.

The amplifier circuit 10 is not exhaustively illustrated in FIG. 1, and the amplifier circuit 10 can include additional components that are not shown. For example, one or more resistors or other circuit components can be coupled between the transistor Q1 and an upper rail voltage V+, between the transistor Q2 and an upper rail voltage V+, between the current source I1 and the lower rail voltage V−, between the current source I2 and the lower rail voltage V−, and at other locations. Coupling, blocking, and other capacitors can also be relied upon as would be understood in the field. The upper rail voltage V+ can be any suitable voltage, and the lower rail voltage V− can be any suitable voltage or potential (e.g., including ground potential in some cases) that is less than the upper rail voltage V+. The voltages V+ and V− can be selected, respectively, based on the target biasing voltage or voltage range for the amplifier circuit 10. The difference in potential between the voltages V+ and V− can be any suitable potential difference based on the target biasing voltage or voltage range for the amplifier circuit 10.

The current sources I1 and I2 are representative, and each can be implemented as any suitable type of current source or related biasing circuitry for the transistors Q1 and Q2. Examples of the current sources I1 and I2 include transistor-based current mirrors, current regulators, resistors, and combinations thereof, but the current sources I1 and I2 are not limited to any particular type of implementation.

The amplifier 20 is a type of differential amplifier, and the transistors Q1 and Q2 are a differential pair of bipolar junction transistors. In an ideal case for some amplifier applications, the current densities through the transistors Q1 and Q2 would be the same for the same input potentials and biasing applied to the transistors Q1 and Q2. In practice, however, the current densities through the transistors Q1 and Q2 can be different for the same input potentials and biasing. This difference in current density and gain can also vary depending on manufacturing (process variation and mismatch), biasing, temperature, and other operating factors.

The compensation circuit 30 is configured to compensate for differences in gain among the transistors Q1 and Q2 in the amplifier 20, including to compensate for differences in gain and other operating parameters that can vary depending on manufacturing, biasing, temperature, and other operating factors. As compared to a conventional differential amplifier, in which the emitters of the transistors Q1 and Q2 are directly coupled to each other, the compensation circuit 30 is coupled between the emitters of the transistors Q1 and Q2, between the nodes A and B.

The compensation circuit 30 can alter or adjust the amount of current that flows through the transistors Q1 and Q2. In effect, the compensation circuit 30 alters or adjusts the amount of gain of the transistors Q1 and Q2 and for the amplifier circuit 10. The compensation circuit 30 can be embodied as a variable impedance, such as a variable resistor, as one example. In other examples described below, the compensation circuit 30 can be embodied as a transistor operated in the linear region of operation.

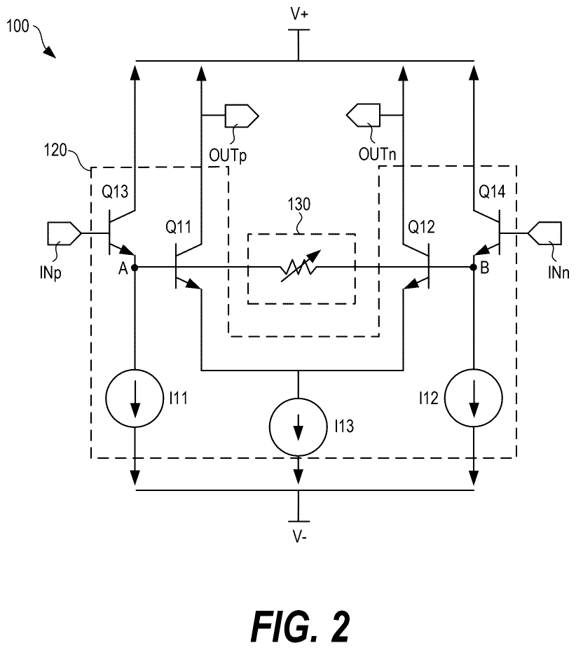

FIG. 2 illustrates another example compensated amplifier circuit 100 (also “amplifier circuit 100”) according to various examples described herein. The amplifier circuit 100 can be embodied in various ways, such as using discrete components, as an integrated circuit device formed on a substrate, or as a combination of discrete components and integrated devices. The amplifier circuit 100 is provided as a representative example of an amplifier stage with a compensation circuit. The amplifier circuit 100 is not exhaustively illustrated in FIG. 2, and the amplifier circuit 100 can include additional components that are not shown.

The amplifier circuit 100 includes an amplifier or amplifier stage 120 (also “amplifier 120”) and a compensation or attenuation circuit 130 (also “attenuation circuit 130”) among possibly other components. The amplifier 120 can be used as an amplifier stage for RF communications, for optical communications, or for other purposes, without limitation. The attenuation circuit 130 is coupled between the nodes A and B in the amplifier 120, as described in further detail below, and includes circuitry for gain compensation of the amplifier 120 through input signal attenuation. Other types and configurations of amplifiers and amplifier circuits can also incorporate and rely upon the gain compensation concepts described herein.

The amplifier 120 includes transistors Q12, Q22, Q23, and Q24 and current sources I11, I12, and I13, among possibly other components. The transistors Q12, Q22, Q23, and Q24 are embodied as bipolar junction transistors in FIG. 2, but the concepts described herein are not limited to use with amplifiers or transistors of any particular type or technology. Q13 is arranged as a common collector in the amplifier 120. The base of the transistor Q13 operates as an input INp (e.g., positive or non-inverting input) of the amplifier 120. The collector of the transistor Q13 is coupled to the upper rail voltage or potential V+, and the emitter of the transistor Q13 is coupled to the current source I11. The emitter of the transistor Q13 is also coupled to the base of the transistor Q11 at node A, as an input to the transistor Q11. The current source I11 is coupled between the node A and the lower rail voltage or potential V−, which can be ground potential in some cases.

The collector of the transistor Q11 is coupled to the upper rail voltage or potential V+, and an output OUTp (e.g., positive or non-inverting output) of the amplifier 120 can be taken from the collector of the transistor Q11. The emitter of the transistor Q11 is coupled to the emitter of the transistor Q12 and to the current source I13. The current source I13 is coupled between the emitters of the transistors Q11 and Q12 and the lower rail voltage or potential V−.

Q14 is arranged as a common collector in the amplifier 120. The base of the transistor Q14 operates as an input INn (e.g., negative or inverting input) of the amplifier 120. The collector of the transistor Q14 is coupled to the upper rail voltage or potential V+, and the emitter of the transistor Q14 is coupled to the current source I12. The emitter of the transistor Q14 is also coupled to the base of the transistor Q12 at node B, as an input to the transistor Q12. The current source I12 is coupled between the node B and the lower rail voltage or potential V−. The collector of the transistor Q12 is coupled to the upper rail voltage or potential V+, and an output OUTn (e.g., negative or inverting output) of the amplifier 120 can be taken from the collector of the transistor Q12. The emitter of the transistor Q12 is coupled to the emitter of the transistor Q11 and to the current source I13.

The current sources I11, I12, and I13 are representative, and each can be implemented as any suitable type of current source or related biasing circuitry for the transistors Q1 and Q2. Examples of the current sources I1 and I2 include transistor-based current mirrors, current regulators, resistors, and combinations thereof, but the current sources I11, I12, and I13 are not limited to any particular type of implementation.

The amplifier 120 is a type of differential amplifier, and the transistors Q11 and Q12 are a differential pair of bipolar junction transistors. The transistors Q13 and Q14 provide an input amplifier stage for the transistors Q11 and Q12. In an ideal case for some amplifier applications, the current densities through the transistors Q13 and Q14 would be the same for the same input potentials and biasing applied to the transistors Q13 and Q14. In practice, however, the current densities through the transistors Q13 and Q14 can be different for the same input potentials and biasing. This difference in current density and gain can also vary depending on manufacturing, biasing, temperature, and other operating factors.

The attenuation circuit 130 is configured to compensate for differences in gain among the transistors Q13 and Q14 in the amplifier 120, including to compensate for differences in gain and other operating parameters that can vary depending on manufacturing, biasing, temperature, and other operating factors. The attenuation circuit 130 also acts as a type of attenuator at the inputs of the Q11 and Q12 differential pair. The attenuation circuit 130 is coupled between the emitters of the transistors Q13 and Q14, between the nodes A and B. The attenuation circuit 130 can alter or adjust the amount of current that flows through the transistors Q13 and Q14 and acts as an attenuator at the inputs of the Q11 and Q12 differential pair. In the example shown in FIG. 2, the attenuation circuit 130 is embodied as a variable resistor or impedance. In other cases, the attenuation circuit 130 can be implemented using a transistor operated in the linear region of operation as described below.

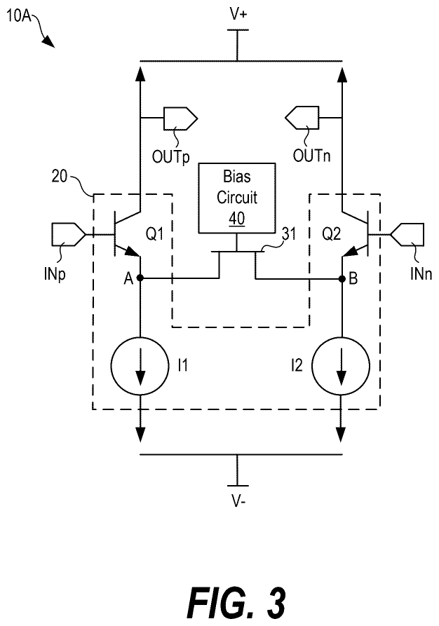

FIG. 3 illustrates another example compensated amplifier circuit 10A according to various examples described herein. The amplifier circuit 10A can be embodied in various ways, such as using discrete components, as an integrated circuit device formed on a substrate, or as a combination of discrete components and integrated devices. The amplifier circuit 10A is provided as a representative example of an amplifier stage with a compensation circuit. The amplifier circuit 10A is not exhaustively illustrated in FIG. 3, and the amplifier circuit 10A can include additional components that are not shown.

The amplifier circuit 10A is similar to the amplifier circuit 10 shown in FIG. 1. However, in the amplifier circuit 10A, the compensation circuit 30 (see FIG. 1) is implemented as a variable impedance transistor 31 (also “transistor 31”) and a bias circuit 40 (also “bias circuit 40”) coupled to the transistor 31. The bias circuit 40 provides biasing for the transistor 31 with PVT correction aspects and features, as described below. The transistor 31 can be embodied as a FET, such as an NFET or a PFET depending on the process type and design of the amplifier circuit 10A. The transistor 31 includes drain, source, and gate terminals as would be understood in the field. The drain of the transistor 31 can be coupled to the node A, and the source of the transistor 31 can be coupled to the node B. Alternatively, the drain of the transistor 31 can be coupled to the node B, and the source of the transistor 31 can be coupled to the node A. The drain and source of the transistor 31 can be interchangeable in some cases (e.g., where the drain terminal and source terminal are at the same quiescent potential). In some cases, the transistor 31 can be implemented as two or more transistors coupled in parallel or in series. Thus, the transistor 31 depicted in FIG. 3 is representative of one, two, or more transistors among the embodiments depending on the design.

During operation of the amplifier circuit 10A, the gain of the transistors Q1 and Q2, the potentials at the nodes A and B, and other operating conditions of the amplifier circuit 10A will vary in part due to changes in the rail voltages V+ and V−, the operating temperature, and other factors. The transistor 31 is relied upon in the amplifier circuit 10A, in part, to help compensate for changes in the gain of the transistors Q1 and Q2 and other manufacturing and operating variations of the amplifier circuit 10A. More particularly, the transistor 31 can be biased for operation as a type of variable impedance or resistance in the amplifier circuit 10A. The resistance provided by the transistor 31 can help to compensate for changes in the gain of the transistors Q1 and Q2 and other operating variations of the amplifier circuit 10A. The transistor 31 can be referred to as a variable impedance transistor in the amplifier circuit 10A. As a resistor, the transistor 31 also operates in part as a type of broadband attenuator.

To operate the transistor 31 as a variable impedance, the bias circuit 40 is configured to maintain the transistor 31 in the linear mode of operation, where the transistor 31 will appear as a type of variable impedance between the nodes A and B. More particularly, the bias circuit 40 is configured to generate one or more bias voltages for one or more terminals of the transistor 31, including for the gate terminal of the transistor 31. The bias circuit 40 generates the bias voltages to maintain the transistor 31 in the linear mode of operation. As described in further detail below, a primary function of the bias circuit 40 is to maintain the bias voltages for the transistor 31 to within safe operating potentials or voltage ranges, despite process, voltage, and temperature variations that may occur in the amplifier circuit 10A during operation.

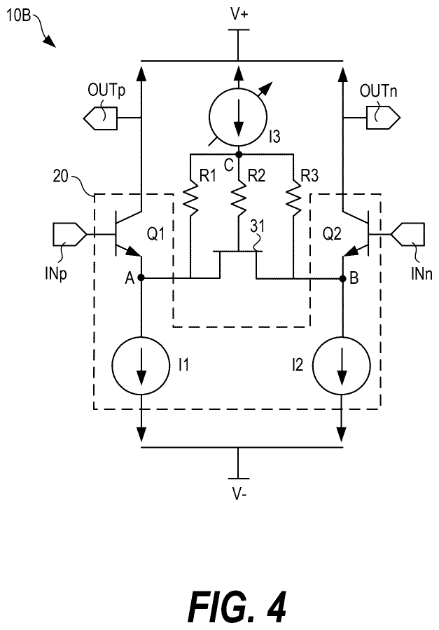

FIG. 4 illustrates another example compensated amplifier circuit 10B. The amplifier circuit 10B is similar to the amplifier circuit 10A shown in FIG. 3. In the amplifier circuit 10B, the bias circuit 40 (see FIG. 3) is implemented as a variable current source I3 and a current divider network of resistors R1, R2, and R3. The variable current source I3 and resistors R1, R2, and R3 provides biasing for the transistor 31 with PVT correction aspects and features. The current divider network of resistors R1, R2, and R3 is coupled in parallel between an output of the variable current source I3 and the drain, source, and gate terminals of the transistor 31. The resistor R1 is coupled between the current source I3 and the drain of the transistor 31. The resistor R2 is coupled between the current source I3 and the gate of the transistor 31. The resistor R3 is coupled between the current source I3 and the source of the transistor 31. Alternatively, the R1 can be coupled to the source and R3 can be coupled to the drain of the transistor 31, and the drain and source of the transistor 31 can be interchangeable in some cases (e.g., where the drain terminal is at the same quiescent potential as the source terminal).

The variable current source I3 is representative and can be implemented as a type of current source or related biasing circuit with a variable current output. Examples of the variable current source I3 include transistor-based current mirrors and current regulators, including circuits that will generate a variable current output based on an applied bias voltage, rail voltage, temperature variation, manufacturing variation, or other control factor or combinations thereof. The variable current source I3 is not limited to any particular type of implementation.

The current source I3 can be designed to source a relatively small fraction of the current that flows through the transistors Q1 and Q2 in operation, i.e., currents I1 and I2, such as about 0.1-3% of the current that flows through the transistors Q1 and Q2. Thus, the sizes (e.g., channel width, channel length, etc.) of any transistors in the current source I3 can be significantly smaller than the transistors in current source I1 and I2. An aspect ratio of about 1:100 is an example sizing ratio between the transistors in the current source I3 (i.e., relative size of 1) and the transistors in I1 and I2 (i.e., relative size of 100). The aspect ratio can vary and be optimized as needed.

The current source I3 is designed and configured to generate an output current to the node C. The output current can vary to some extent over time during operation of the amplifier circuit 10B, such as with changes in biasing voltages, operating temperature, and other characteristics. The generation of and changes in the output current, when applied to control the transistor 31 as a variable impedance, can help to compensate the gain of the amplifier 20, including to compensate for variations in current density, process or threshold voltages, and other operating variations that may otherwise occur.

The resistors R1, R2, and R3 can be designed as relatively large impedances to reduce power consumption. Among the resistors R1, R2, and R3, the impedances of R1 and R3 are matched (i.e., are the same or substantially the same) in preferred embodiments. The resistors R1, R2, and R3 can all be matched in some cases, although it is not necessary for R2 to be matched with R1 and R3 in all cases. R2 can be relied upon to reduce the effect or impact of any parasitic capacitance in the gate of the transistor 31, although R2 can be omitted in some cases.

In operation, the current sourced by the current source I3 flows through the resistors R1, R2, and R3 and primarily through the resistors R1 and R3. The current sourced by the current source I3 can vary over time in some cases depending on biasing, temperature, and other operating factors that can vary over time. The current through the resistors R1 and R3 flows through the nodes A and B, respectively, and through the current sources I1 and I2 to the lower rail voltage V−. Without significant current flowing through the resistor R2, the voltage or potential at R2 is the same or substantially the same at both ends of R2, and the potential at the gate of the transistor 31 can be substantially the same as the potential at node C. The potential at node C depends on the potentials at nodes A and B, the parallel combination of R1 and R3, and the output current generated by the current source I3.

Implementation of the bias circuit 40 (see FIG. 3) using the variable current source I3 and the parallel combination of resistors R1, R2, and R3 avoids complex feedback loops and other control circuitry that consumes relatively large amounts of power and/or area. The variable current source I3 and resistors R1, R2, and R3 are also capable of maintaining the gate-to-drain V_{GD} and the gate-to-source V_{GS} voltages of the transistor 31 within an acceptable range of potentials, to avoid damage to the transistor 31. The variable current source I3 and resistors R1, R2, and R3 can be designed to maintain the V_{GD} and V_{GS} voltages to a target voltage, such as a target voltage between 0.5-2.5V±2%, 5%, or 10% of the target voltage. The variable current source I3 and resistors R1, R2, and R3 can maintain V_{GD} and V_{GS} within the target voltage or voltage range better than other approaches, while also offering a simple solution without feedback or control loops or significant power consumption.

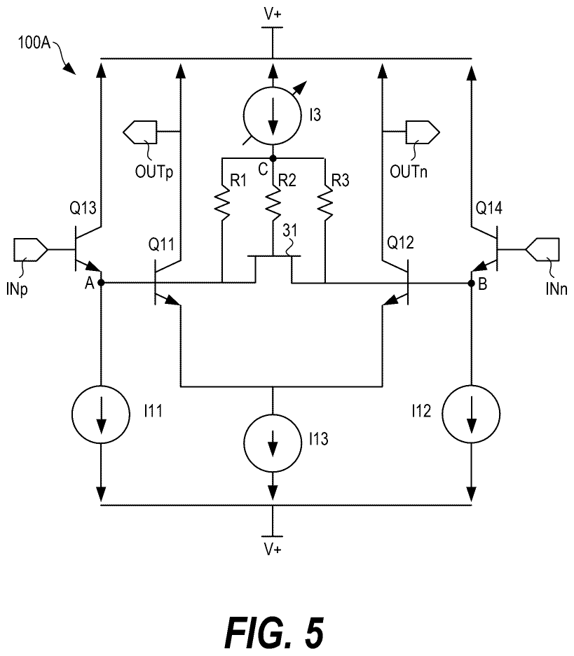

FIG. 5 illustrates another example compensated amplifier circuit 100A. The amplifier circuit 100A is similar to the amplifier circuit 100 shown in FIG. 2. In the amplifier circuit 100A, the attenuation circuit 130 (see FIG. 2) is implemented as the variable current source I3 and the current divider network of resistors R1, R2, and R3. The current divider network of resistors R1, R2, and R3 is coupled in parallel between an output of the variable current source I3 and the drain, source, and gate terminals of the transistor 31. The resistor R1 is coupled between the current source I3 and the drain of the transistor 31. The resistor R2 is coupled between the current source I3 and the gate of the transistor 31. The resistor R3 is coupled between the current source I3 and the source of the transistor 31. Alternatively, the R1 can be coupled to the source and R3 can be coupled to the drain of the transistor 31, and the drain and source of the transistor 31 can be interchangeable in some cases (e.g., where the drain terminal is at the same quiescent potential as the source).

The current source I3 can be designed to source a relatively small fraction of the current that flows through the transistors Q13 and Q14 in operation, such as about 0.1-3% of the current that flows through the transistors Q13 and Q14. Thus, the sizes (e.g., channel width, channel length, etc.) of any transistors in the current source I3 can be significantly smaller than the transistors in I11 and I12. An aspect ratio of about 1:100 is an example sizing ratio between the transistors in the current source I3 (i.e., relative size of 1) and the transistors in current sources I11 and I12 (i.e., relative size of 100). The aspect ratio can vary and be optimized as needed.

The current source I3 is designed and configured to generate an output current to the node C. The output current can vary to some extent over time during operation of the amplifier circuit 100A, such as with changes in biasing voltages, operating temperature, and other characteristics. The changes in the output current from the current source I3, when applied to control the transistor 31 as a variable impedance attenuator, can help to compensate the gain of the amplifier 100A through attenuation of the inputs to the transistors Q11 and Q12.

The resistors R1, R2, and R3 can be designed as relatively large impedances to reduce power consumption. Among the resistors R1, R2, and R3, the impedances of R1 and R3 are matched (i.e., are the same or substantially the same) in preferred embodiments. The resistors R1, R2, and R3 can all be matched in some cases, although it is not necessary for R2 to be matched with R1 and R3 in all cases. R2 can be relied upon to reduce the effect or impact of any parasitic capacitance in the gate of the transistor 31, although R2 can be omitted in some cases.

In operation, the current sourced by the current source I3 flows through the resistors R1, R2, and R3 and primarily through the resistors R1 and R3. The current sourced by the current source I3 can vary over time in some cases depending on biasing, temperature, and other operating factors that can vary over time. The current through the resistors R1 and R3 flows through the nodes A and B, respectively, and through the current sources I11 and I12 to the lower rail voltage V−. Without significant current flowing through the resistor R2, the voltage or potential at R2 is the same or substantially the same at both ends of R2, and the potential at the gate of the transistor 31 can be substantially the same as the potential at node C. The potential at node C depends on the potentials at nodes A and B, the parallel combination of R1 and R3, and the output current generated by the current source I3.

Use of the variable current source I3 and the parallel combination of resistors R1, R2, and R3 avoids complex feedback loops and other control circuitry that consumes relatively large amounts of power. The variable current source I3 and resistors R1, R2, and R3 are also capable of maintaining the gate-to-drain V_{GD} and the gate-to-source V_{GS} voltages of the transistor 31 within an acceptable range of potentials, to avoid damage to the transistor 31. The variable current source I3 and resistors R1, R2, and R3 can be designed to maintain the V_{GD} and V_{GS} voltages to a target voltage, such as a target voltage between 0.5-2.5V±2%, 5%, or 10% of the target voltage. The variable current source I3 and resistors R1, R2, and R3 can maintain V_{GD} and V_{GS} within the target voltage or voltage range better than other approaches, while also offering a simple solution without feedback or control loops or significant power consumption.

The transistor amplifiers described herein, including the transistors Q1, Q2, Q12, Q22, Q23, and Q24 in the amplifiers 20 and 120, can be implemented as a range of different types of transistors formed in a range of different semiconductor materials. The variable impedance transistor 31 can also be implemented as a range of different types of transistors formed in a range of different semiconductor materials. The transistors can be formed as FETs, although the concepts can be applied to other types of transistors. Among other types of FET transistors, the transistors described herein can be formed as high-electron mobility transistors (HEMTs), pseudomorphic high-electron mobility transistors (pHEMTs), metamorphic high-electron mobility transistors (mHEMTs), and other types of transistors. The FETs can include metal oxide or insulator semiconductor (MOSFET or MISFET) transistors and metal-semiconductor field-effect transistor (MESFETs). The transistors can include one or more field plates, such as source-connected field plates, gate-connected field plates, or both source-connected and gate-connected field plates. The transistors can be implemented in gallium arsenide (GaAs), gallium nitride (GaN), GaN materials, and other semiconductor materials on or over a range of different substrates. As non-limiting examples, the transistors can be structured as enhancement or depletion mode FET transistors, such as a depletion mode GaAs pHEMT transistors, as GaN HEMT transistors, as GaN materials HEMT transistors, or as related power transistors.

The transistors and other active devices described herein can be formed using group III-V semiconductor materials and semiconductor manufacturing processes. The group III elemental materials include scandium (Sc), aluminum (Al), gallium (Ga), and indium (In), and the group V elemental materials include nitrogen (N), phosphorus (P), arsenic (As), and antimony (Sb)). Thus, in some examples, the concepts can be applied to group III-V active semiconductor devices, such as the III-Nitrides (aluminum (Al)-, gallium (Ga)-, indium (In)-, and alloys (AlGaIn)-based Nitrides), GaAs, InP, InGaP, AlGaAs, etc. devices. However, the concepts may be applied to transistors and other active devices formed from other semiconductor materials.

The concepts described herein can be embodied by GaN-on-Si transistors and devices, GaN-on-SiC transistors and devices, as well as other types of semiconductor materials. As used herein, the phrase “gallium nitride material(s)” or “GaN material(s)” refers to gallium nitride and any of its alloys, such as aluminum gallium nitride (AlₓGa₍₁₋ₓ₎N), indium gallium nitride (In_{y}Ga_{(1-y)}N), aluminum indium gallium nitride (AlₓIn_{y}Ga_{(1-x-y)}N), gallium arsenide phosphide nitride (GaAsₐP_{b}N_{(1-a-b)}), aluminum indium gallium arsenide phosphide nitride (AlₓIn_{y}Ga_{(1-x-y)}AsₐP_{b}N_{(1-a-b)}), among others. Typically, when present, arsenic and/or phosphorous are at low concentrations (e.g., less than 5 weight percent). The gallium nitride materials can be n-type doped, p-type doped, or unintentionally doped (UID).

In embodiments with high concentrations of gallium, gallium nitride material has a high concentration of gallium and includes little or no aluminum or indium. In high gallium concentration embodiments, the sum of (x+y) may be less than 0.4 in some cases, less than 0.2 in some cases, less than 0.1 in some cases, or even less in other cases. The term “gallium nitride” or “GaN” refers directly to gallium nitride, exclusive of its alloys (i.e., x=y=a=b=0). The GaN can be n-type doped, p-type doped, or unintentionally doped (UID).

In view of the limitations of the semiconductor manufacturing and processing techniques available in the field, the terms “approximately” and “about” reflect a certain inability (or uncertainty) to precisely control the exact dimensions of certain features described herein. Depending on the level of precision that can be achieved using the commercially available semiconductor processing tools available at the time, the terms “approximately” and “about” may be used to mean within ±20% of a target value for some features, within ±10% of a target value for some features, within ±5% of a target value for some features, and within ±2% of a target value for some features. The terms “approximately” and “about” may include the target value.

The concepts described herein can be combined in one or more embodiments in any suitable manner, and the features discussed in the embodiments are interchangeable in some cases. Example embodiments are described herein, although a person of skill in the art will appreciate that the technical solutions and concepts can be practiced in some cases without all of the specific details of each example. Additionally, substitute or equivalent steps, components, materials, and the like may be employed. It should also be appreciated that some well-known process steps, semiconductor material layers, semiconductor device features, and other features have been omitted to avoid obscuring the concepts.

Although relative terms such as “on,” “below,” “upper,” “lower,” “top,” “bottom,” “right,” and “left” may be used to describe the relative spatial relationships of certain structural features, these terms are used for convenience only, as a direction in the examples. Thus, if a structure is turned upside down, the “upper” component will become a “lower” component. When a structure or feature is described as being “on” (or formed on) another structure or feature, the structure can be positioned directly on (i.e., contacting) the other structure, without any other structures or features intervening between the structure and the other structure. When a structure or feature is described as being “over” (or formed over) another structure or feature, the structure can be positioned over the other structure, with or without other structures or features intervening between them. When two components are described as being “coupled to” each other, the components can be electrically coupled to each other, with or without other components being electrically coupled and intervening between them. When two components are described as being “directly coupled to” each other, the components can be electrically coupled to each other, without other components being electrically coupled between them.

Terms such as “a,” “an,” “the,” and “said” are used to indicate the presence of one or more elements and components. The terms “comprise,” “include,” “have,” “contain,” and their variants are used to be open ended and may include or encompass additional elements, components, etc., in addition to the listed elements, components, etc., unless otherwise specified. The terms “first,” “second,” etc. may be used as differentiating identifiers of individual or respective components among a group thereof, rather than as a descriptor of a number of the components, unless clearly indicated otherwise.

Although embodiments have been described herein in detail, the descriptions are by way of example. The features of the embodiments described herein are representative and, in alternative embodiments, certain features and elements can be added or omitted. Additionally, modifications to aspects of the embodiments described herein can be made by those skilled in the art without departing from the spirit and scope of the present invention defined in the following claims, the scope of which are to be accorded the broadest interpretation so as to encompass modifications and equivalent structures.

Therefore, the following is claimed:

1. A compensated amplifier circuit comprising:
an amplifier circuit; and
a variable impedance compensation circuit coupled between two nodes in the amplifier circuit, the variable impedance compensation circuit comprising a variable current source, a current divider network, and a variable impedance transistor.

2. The compensated amplifier circuit according to claim 1, wherein two terminals of the variable impedance transistor are coupled between the two nodes in the amplifier circuit.

3. The compensated amplifier circuit according to claim 1, wherein:
the amplifier circuit comprises a differential pair of transistors;
the variable impedance transistor comprises a field effect transistor; and
drain and source terminals of the variable impedance transistor are coupled between the two nodes in the amplifier circuit.

4. The compensated amplifier circuit according to claim 3, wherein the drain and source terminals of the variable impedance transistor are coupled between emitter or drain nodes of the differential pair of transistors.

5. The compensated amplifier circuit according to claim 1, wherein the current divider network comprises a plurality of resistors coupled in parallel between an output of the variable current source and terminals of the variable impedance transistor.

6. The compensated amplifier circuit according to claim 1, wherein the current divider network comprises a matched pair of resistors coupled in parallel between an output of the variable current source and terminals of the variable impedance transistor.

7. The compensated amplifier circuit according to claim 1, wherein:
the current divider network comprises a plurality of resistors coupled in parallel between an output of the variable current source and terminals of the variable impedance transistor;
a first resistor among the plurality of resistors is coupled between an output of the variable current source and a source terminal of the variable impedance transistor; and
a second resistor among the plurality of resistors is coupled between an output of the variable current source and a drain terminal of the variable impedance transistor.

8. The compensated amplifier circuit according to claim 7, wherein the first resistor and the second resistor comprise a matched pair of resistors.

9. The compensated amplifier circuit according to claim 7, wherein a third resistor among the plurality of resistors is coupled between an output of the variable current source and a gate terminal of the variable impedance transistor.

10. A compensated amplifier circuit comprising:
an amplifier circuit; and
a variable impedance compensation circuit comprising a variable current source, a current divider network, and a variable impedance transistor, wherein the current divider network comprises a plurality of resistors coupled in parallel between an output of the variable current source and terminals of the variable impedance transistor.

11. The compensated amplifier circuit according to claim 10, wherein two terminals of the variable impedance transistor are coupled between two nodes in the amplifier circuit.

12. The compensated amplifier circuit according to claim 10, wherein the current divider network comprises a matched pair of resistors coupled in parallel between an output of the variable current source and terminals of the variable impedance transistor.

13. The compensated amplifier circuit according to claim 10, wherein:
a first resistor among the plurality of resistors is coupled between an output of the variable current source and a first terminal of the variable impedance transistor; and
a second resistor among the plurality of resistors is coupled between an output of the variable current source and a second terminal of the variable impedance transistor.

14. The compensated amplifier circuit according to claim 13, wherein the first resistor and the second resistor comprise a matched pair of resistors.

15. The compensated amplifier circuit according to claim 13, wherein a third resistor among the plurality of resistors is coupled between an output of the variable current source and a gate terminal of the variable impedance transistor.

16. A compensated amplifier circuit comprising:
an amplifier circuit comprising an input amplifier stage of common collector transistors and a differential pair of transistors; and
a variable impedance compensation circuit coupled between two nodes in the amplifier circuit, the variable impedance compensation circuit comprising a variable current source, a current divider network, and a variable impedance transistor, wherein the current divider network comprises a plurality of resistors coupled in parallel between an output of the variable current source and terminals of the variable impedance transistor.

17. The compensated amplifier circuit according to claim 16, wherein two terminals of the variable impedance transistor are coupled between the two nodes in the amplifier circuit.

18. The compensated amplifier circuit according to claim 16, wherein the current divider network comprises a matched pair of resistors coupled in parallel between an output of the variable current source and terminals of the variable impedance transistor.

19. The compensated amplifier circuit according to claim 16, wherein:
a first resistor among the plurality of resistors is coupled between an output of the variable current source and a first terminal of the variable impedance transistor; and
a second resistor among the plurality of resistors is coupled between an output of the variable current source and a second terminal of the variable impedance transistor.

20. The compensated amplifier circuit according to claim 19, wherein the first resistor and the second resistor comprise a matched pair of resistors.
